(19) United States
(12) Patent Application Publication
(10) Pub. No.: US 2011/0027999 A1
(43) Pub. Date: Feb. 3, 2011

(54) ETCH METHOD IN THE MANUFACTURE OF AN INTEGRATED CIRCUIT

(75) Inventors: Terry G. Sparks, Austin, TX (US); Rauf Shahid, Pleasanton, CA (US)

Correspondence Address: FREESCALE SEMICONDUCTOR, INC.;LAW DEPARTMENT, 7700 WEST PARMER LANE MD:TX32/PL02, AUSTIN, TX, 78729, US

(73) Assignee: FREESCALE SEMICONDUCTOR, INC., Austin, TX (US)

(21) Appl. No.: 12/377,348

(22) PCT Filed: Aug. 16, 2006
(86) PCT No.: PCT/IB06/03127

§ 371 Date: Jul. 9, 2010

(51) Int. Cl. H01L 21/465

(52) U.S. Cl. 438/712; 257/E21.485

(57) ABSTRACT

The present invention provides a method for etching a substrate in the manufacture of a semiconductor device, the method comprising contacting a surface of the substrate with ions extracted from a plasma formed from a gas comprising one or more of an oxygen-containing species, a nitrogen-containing species and an inert gas, and separately contacting the surface of the substrate with a plasma formed from a gas comprising a fluorine-containing species.

### TECHNICAL FIELD

The present invention relates to semiconductor processing and, in particular, to a method for etching a substrate.

### BACKGROUND

Semiconductor manufacturers are continuously striving to reduce the size of features contained in integrated circuits, and they are now facing the challenge of engineering features with nanoscale precision. In addition, the complexity of the individual features in integrated circuits is increasing as new device structures are developed. The development of more complex integrated circuits has also been facilitated by the use of new dielectric and metal materials.

One well-known approach to the formation of features on the surface of a substrate is illustrated in FIGS. 1A to D.

These figures show the formation of a trench structure in the surface of the substrate, and the approach is useful in illustrating the different types of steps involved in semiconductor processing. The Figures illustrate the following types of process:
i. in FIG. 1A, a thin layer structure is shown in which a first layer (100) has been deposited on top of a second layer (105);
ii. the (selective) deposition of a mask layer (110) may then be carried out to produce the structure illustrated in FIG. 1B;
iii. the exposed surface of the substrate (100) is then etched to expose the underlying layer, producing the structure illustrated in FIG. 10; and
iv. finally, the mask is removed from the un-etched dielectric to produce the structure illustrated in FIG. 1D.

Other methods of producing features in an integrated circuit, such as methods of forming non-planar devices, are well-known in the art.

The present inventors have found that one of the limitations on the size and complexity of features in an integrated circuit is the method of etching used in conventional methods of manufacturing. In particular, the present inventors have found that current methods of etching are not sufficiently selective or precise. Some of the prior art methods are also impractically slow for use in the large-scale manufacture of integrated circuits.

An etching method should ideally be precise so that it etches a surface uniformly and at a predictable rate. For example, when a patterned surface is etched, it is beneficial that the etching occurs only in a direction perpendicular to the surface. In this way, well-defined features are formed on the surface. In the case of the formation of a damascene structure on the surface, features with high aspect ratios are formed in the surface using a precise etching method.

In addition, an etching method should ideally be highly selective, so that the etching material only removes the desired material from the surface. For example, it is sometimes required that a very thin layer (e.g. less than 5 nm), deposited on an underlying material, is etched so that only the thin layer and not the underlying material is etched. It has been found that the desired selectivity is particularly difficult to achieve for new dielectric and metal materials which have been developed for use in the manufacture of nanoscale features in integrated circuits. Examples of these new dielectrics and metals include HfO₂, ZrO₂, HfZrOₓ, HfSiOₓ, Mo₂N, TaC, and Ru.

In general, there are two types of etching known in the prior art. The first type of etching involves the treatment of a surface with a chemical or gaseous etching material in a single step. An example of this type of etching is described in PCT/US1999/08798. In this patent application, a silicon dioxide layer on top of an underlying conductive layer is etched by a plasma formed from a gas containing a fluorocarbon, nitrogen, oxygen and an inert carrier.

This first type of conventional etching generally has the advantage that it can achieve reasonably high etch rates. However, these high etch rates are achieved at the expense of precision and selectivity. These factors become especially important for ultra-thin nanoscale films or layers, and therefore this type of technique is especially unsuitable for the precise and selective production of nanoscale features. (Nanoscale as used herein refers to features with dimensions on the surface below approximately 50 nm in size). In particular, when this technique is used to etch a thin layer on top of an underlying material, the technique's lack of selectivity can lead to damage or excessive loss of the underlying layer and any features contained in it. Furthermore, this type of technique can lead to non-uniform etching, which, when used over a large surface area, can cause damage resulting from over-etching of the underlying layer.

A second approach to the etching of the surface of a substrate is Atomic Layer Etching (ALE). This method is illustrated for a silicon surface in FIGS. 2A to C. The first step of the process, illustrated in FIG. 2A, typically involves exposing the surface of a substrate, such as silicon, to a gas (comprising ‘X’ in FIG. 2A) such as chlorine, HCl and/or bromine. The gas is chemically absorbed onto the surface, as shown in FIG. 2B. In a subsequent step, illustrated in FIG. 2C the surface is bombarded by an ionized inert gas such as argon (Ar⁺), and SiXₙ molecules are removed from the surface.

ALE is described in detail in S. D. Park et a/.; Jap. J. App. Phys. 44, 389 (2005). This paper shows that ALE has the advantage over other etching techniques because it can be used to etch the surface of substrates very precisely and selectively. However, because ALE removes only a single atomic layer or less with each cycle of gas absorption/desorption, it is a very time-consuming methodology. Therefore ALE has the disadvantage that it is a slow process, and not easily adapted to use in the large scale manufacture of integrated circuits. ALE is further described in T. Matsuura et al.; Appl. Phys. Lett. 63, 2803 (1993).

Finally, an alternate method of etching a substrate is described in US2003/0194874. However, this patent application is directed at a method of broadening a trench already existing on a surface, rather than to the production of new features on a surface.

### BRIEF DESCRIPTION OF THE DRAWINGS

The present invention will now be described further, by way of example, with reference to the following drawings in which:

FIGS. 1A to D illustrate a prior art method of forming a patterned semiconductor substrate.

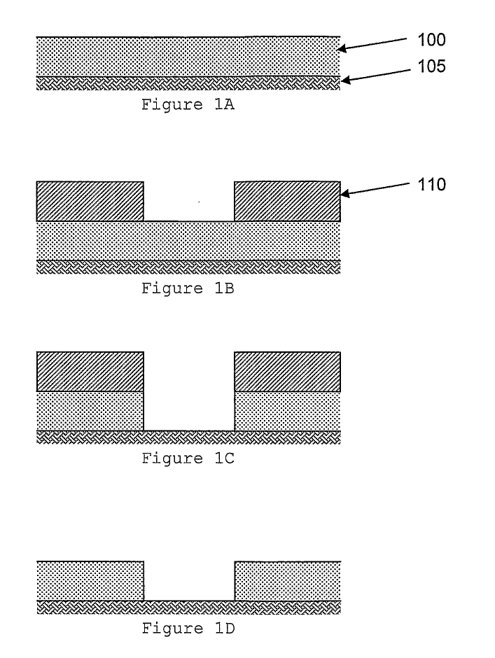

FIGS. 2A to C show the steps of Atomic Layer Etching. FIG. 2A shows a silicon surface prior to absorption of a reactant gas; FIG. 2B shows the surface with absorbed gas; FIG. 2C shows the surface after bombardment with ionized argon. One layer or less of silicon atoms is seen to have been removed by the one cycle of ALE treatment. The process can then be repeated until the desired amount of the material is removed.

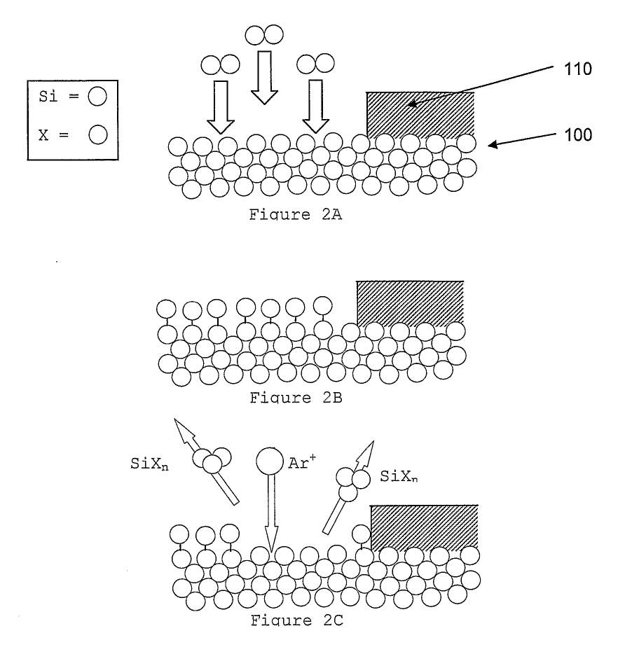

FIGS. 3A to C illustrate a first embodiment of the present invention.

FIG. 4 is a flow diagram of the steps involved in the method of the first embodiment of the present invention.

FIGS. 5A to C show molecular simulations of O⁺ ions penetrating a silicon lattice, as described in the first embodiment of the present invention.

FIGS. 6A and B show the effect of O⁺ ion energy on thickness of oxidized Si layer, as described in the first embodiment of the present invention.

FIG. 7A to C show a second embodiment of the present invention.

FIG. 8 is a flow diagram of the steps involved in the second embodiment of the present invention.

FIGS. 9A to C show molecular simulations of a fluorocarbon film being deposited on the surface of a substrate over time, as described in the second embodiment of the present invention.

FIGS. 10A and B show molecular simulations of a fluorocarbon film being deposited on the surface of a substrate dependent on the energy of the fluorocarbon plasma from which the fluorocarbon film is deposited, as described in the second embodiment of the present invention.

### DETAILED DESCRIPTION

The present invention aims at solving at least some of the problems associated with the prior art. Accordingly, the present invention describes a method for etching a substrate in the manufacture of a semiconductor device, the method comprising contacting a surface of the substrate with ions extracted from a plasma formed from a gas comprising one or more of an oxygen-containing species, a nitrogen-containing species and/or an inert gas, and separately contacting the surface of the substrate with a plasma formed from a gas comprising a fluorine-containing species.

An inert gas as described herein refers to a gas which, under the reaction conditions, will not chemically react with the surface of the substrate. As such, chemical reaction is considered to occur for the purposes of this definition if a chemical bond (a covalent bond) is formed between a gas species and a species on the surface. However, chemical reaction for the purposes of this definition does not include the transfer of kinetic energy from a gas species to the surface; equally it does not include simple electron transfer reactions which do not result in the formation of a chemical bond.

The inert gas may comprise a noble gas, for example one or more of helium, neon, krypton, xenon, and argon.

In addition, as described below in relation to the two illustrated embodiments, the fluorine-containing species may be a fluorocarbon. It may comprise, for example, one or more of CF₄, CHF₃, CH₂F₂, C₂F₆, C₄F₆, octafluorocyclobutane and C₅F₈. The gas comprising the fluorine-containing species may be essentially oxygen-free.

The oxygen-containing species may comprise one or more of O₂, CO, CO₂, N₂O and H₂O.

The nitrogen-containing species may comprise N₂.

The present invention will now be described in relation to two particular embodiments.

In a first embodiment, the present invention describes a method as claimed in any one of the preceding claims, the method comprising:
(A) forming a first plasma from a first gas comprising an oxygen-containing species;
(B) extracting ions from the first plasma;
(C) contacting a surface of the substrate with the ions extracted from the first plasma;
(D) forming a second plasma from a second gas comprising a fluorine-containing species; and
(E) contacting the surface of the substrate with at least a portion of the second plasma.

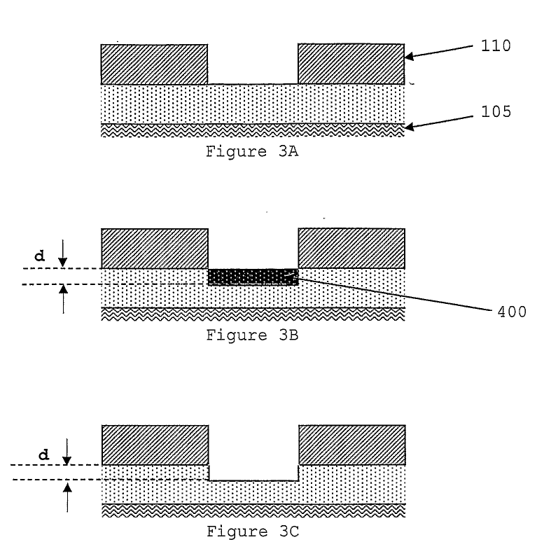

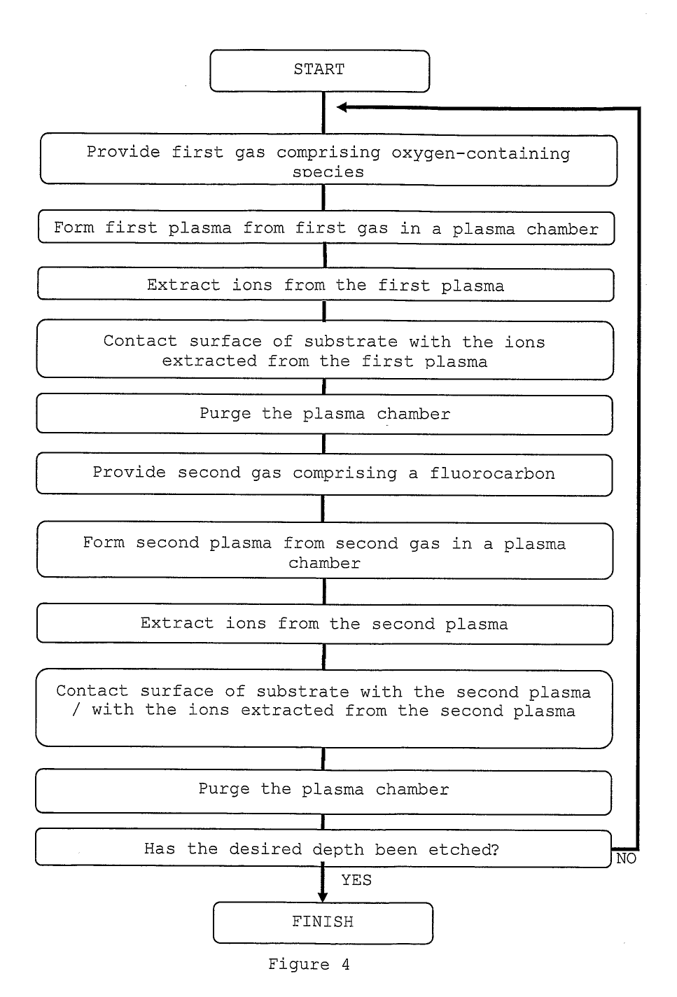

The method of the present invention in its first embodiment is illustrated in FIGS. 3 and 4. FIG. 3A shows a substrate prior to etching. The substrate comprises a mask (110) on top of a first layer (100), which is in turn on top of a second layer (105). The substrate is exposed to ions extracted from a first plasma comprising an oxygen-containing species. The parts of the substrate exposed to the ions are oxidized by the ions. FIG. 3B shows the substrate after this first stage of etching, with the oxidized region represented by the label ‘400’. The substrate is then exposed to the second plasma, and FIG. 3C shows the substrate after this second stage of etching. The depth of one cycle of the etching is illustrated by ‘d’. Methods of plasma oxidation of a surface of a substrate in the manufacture of a semiconductor device are well-known in the art. They are, for example, described in H. Kuroki at al.; J. Appl. Phys. 71, 5278 (1992). This paper shows that the surface is oxidized at a predictable rate at a predetermined plasma density, pressure, RF power and reaction time. The present inventors have recognised that the oxidation process can be better controlled if only ions from the plasma are used to oxidize the surface. It is possible that neutral species may cause unwanted side reactions on the surface, and therefore the use of only ions to oxidize the surface has been found to lead to a more controlled reaction. In addition, in this first embodiment, the surface may be oxidized to a pre-determined depth when the surface is exposed to ions extracted from the first plasma in step C. These ions will usually be oxygen ions (such as O₂⁺ and O⁺), although they may also contain other charged species.

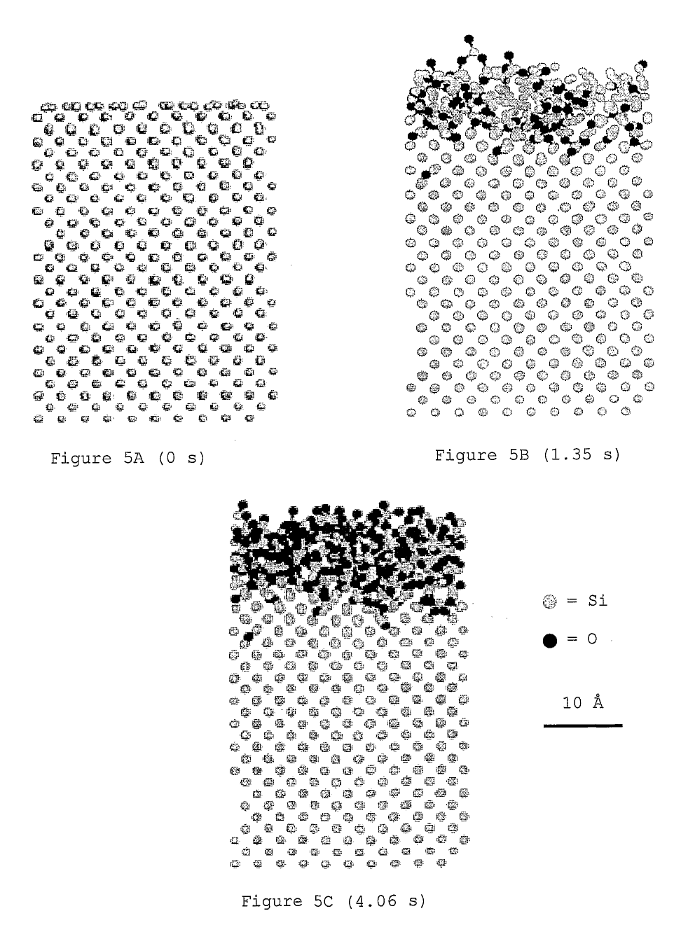

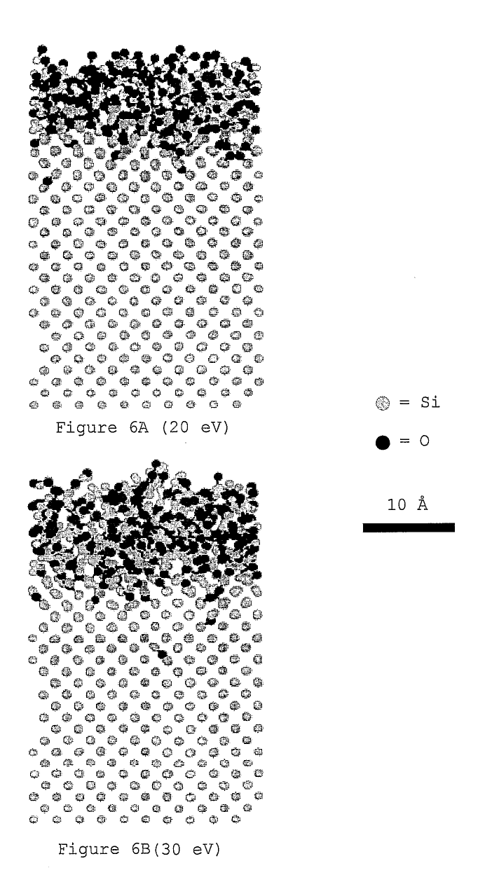

The present inventors have also found that the oxidation process can be precisely controlled if only ions with a predetermined range of energies are used. In order to illustrate this control, a series of simulations has been carried out to model the penetration of oxygen (O⁺) ions of a silicon lattice over time. These simulations were carried out using the molecular dynamics method. Details of the computational model that is used for these simulations is described in the following paper: V. V. Smirnov, A. V. Stengach, K. G. Gaynullin, V. A. Pavlovsky, S. Rauf, P. J. Stout, and P. L. G. Ventzek, J. Appl. Phys. 97, 093302 (2005). Representative results of these simulations are illustrated in FIGS. 5 and 6.

FIG. 5 shows the rate of penetration of O⁺ ions into a silicon lattice over time. The silicon atoms in the lattice are represented in grey and the oxygen atoms that have penetrated the lattice are represented in black. The O⁺ ions exposed to the surface have an energy of 20 eV and collide with the surface at a rate of 1.0×10¹⁵ cm⁻² s⁻¹. The lattice is shown in FIG. 5A before oxidation; in FIG. 5B the lattice is shown having been exposed for 1.35 seconds to the ions; finally, the lattice is shown in FIG. 5C having been exposed to the ions for 4.06 seconds. It can be seen that the oxygen ions are only penetrating to a certain depth, and do not tend to penetrate or diffuse further into the lattice over time.

FIG. 6 shows the extent of penetration of O⁺ ions into a silicon lattice dependant on the energy of the oxygen ions. Both lattices have been exposed to oxygen ions for 4.06 seconds, with a flux density of oxygen atoms colliding with the surface of 1.0×10¹⁵ cm²s⁻¹ The difference between the two results is that the FIG. 6A simulation was run with ions having 20 eV of energy, whereas the FIG. 6B simulation was run with ions having 30 eV of energy. It is observed that the depth to which the oxygen ions penetrate is dependent on the energy of the ions.

These simulations demonstrate that the depth to which these ions penetrate is predictable by controlling ion energy. Therefore by selecting a predetermined range of energies for the ions, a more precise control is achieved over the depth to which the ions penetrate the silicon lattice.

Oxidation by the method of the present invention in this first embodiment may be more precise and selective because oxidation can be directed to occur in a direction perpendicular to the surface. The ions used to oxidize the surface (such as O₂⁺ and O⁺) may be extracted from the plasma sheath (the region at the edge of the plasma) contained in a plasma chamber. The ion energy can also be more precisely controlled using either or both electrostatic or electromagnetostatic lenses that use electric and magnetic fields to appropriately reduce or increase the electron energy.

In addition, the direction of travel of the ions may be controlled and the ions may then be directed perpendicularly towards the surface. As described below, the direction of the flow of ions may be further controlled through collimation. Therefore the direction of propagation of oxidation, which is in the same direction as the ions' kinetic energy vector, can be controlled so that it is also perpendicular to the surface. This is an advantage over the prior art methods in which the direction of oxidation is not controlled and is primarily ruled by factors such as diffusion.

Turning to the individual steps of this embodiment of the present invention, in step A the first gas from which the plasma is formed may comprise an oxygen-containing species. For example it may comprise O₂, or simply be pure oxygen. Oxygen ions can also be obtained from other oxygen-containing gases such as CO, CO₂, N₂O or H₂O. Therefore the term “oxygen-containing species” not only includes within its scope molecular oxygen itself but also molecules which contain one or more oxygen atoms along with other atoms.

The first gas may comprise an oxygen-containing species and a carrier gas, such as an inert gas, for example one or more of argon, helium and/or neon. The carrier gas is effectively inert in its neutral form, although when ionized it may participate in reactions at the surface. The carrier gas may be incorporated to dilute the oxygen gas, so that reaction may be carried out in a controlled manner.

The first gas may be provided in step A at a pressure of 0.1 Pa to 10 Pa, for example 0.5 to 10 Pa. The plasma may be generated at a power of 50 watts to 10 kilowatts in a plasma chamber, for example 50 watts to 3 kilowatts. This power may be provided by radio frequency waves with an oscillation frequency of between 1 MHz and 20 GHz, for example below 3.0 GHz, such as at 13.56 MHz. The plasma density may be 1.0×10⁸ cm³ to 1.0×10¹³ cm³, for example 1.0×10¹⁰ cm³ to 1.0×10¹² cm³.

In step B, ions are extracted from the first plasma. This may be achieved by providing an outlet to a plasma chamber. Ions are extracted from the plasma sheath at the outside of plasma chamber. The energy of the ions can be more precisely controlled using either or both an electrostatic and/or electromagnetostatic lenses that uses electric and magnetic fields to appropriately increase or decrease ion energy.

A means of collimating the ions may also be provided. As a result, the direction of the ions is even more precisely controlled. This may be advantageous because, the substrate will generally only be oxidized (and therefore etched) in the direction of the kinetic energy of the oxidizing ions. Therefore, this may lead to greater precision in the etching method.

It will be understood that, while it is beneficial to extract only ions from the plasma without any neutral species, due to practical considerations a small number of neutral species may also be extracted from the plasma (for example less than 10% by number, or even less than 2% by number). Therefore in step C, the portion of the plasma contacting the surface of the substrate can be considered to contain substantially or essentially only ions.

Ions extracted from the plasma sheath will generally be positively charged. However, methods of extracting negative ions (such as O⁻) from a plasma are known in the art, and may be equally applied to the present invention.

In step C, the ions extracted from the plasma in step B are contacted with the surface of the substrate. The ions may have a pre-determined range of energies. This allows for the more predictable and controlled oxidation of the surface. The upper limit of the energy of the ions may be determined by the physical sputtering threshold energy of the surface of the substrate in question. Above this energy, unwanted sputtering of the atoms from the lattice becomes significant. For some materials, such as silicon, this upper energy may be around 30 eV. However, the sputtering threshold energy is dependent on the material in question and it will depend on the exact nature of the surface of the substrate.

The range of energies of ions may be below 30 eV, or even below 20 eV, such as in the range of 10 to 20 eV. Greater control over the depth to which the ions penetrate may be gained by using a lower energy plasma; however, this gain in control needs to be offset by a reduced depth to which the ions penetrate, and therefore potentially a slower overall process.

It will be understood that ions in the plasma have a range of energies. Therefore, substantially or essentially all of the ions may have an energy within the thresholds described above. For example, because of practical considerations, the portion of the plasma contacted with the surface may contain a total of 5% by number of its species with an energy greater than the above upper limits and less than any lower threshold limit (i.e. 95% of the ions are within the given range). For example, 1% by number of the species may beyond the given thresholds.

The ions in step C may, for example, be provided at a flow rate of between 5 and 10,000 sccm (standard cubic centimetres per minute), for example between 5 and 100 sccm.

It is not necessary to apply heat to the substrate in step C. This is because oxidation is driven by the penetration of the ions into the lattice, and this may occur at room temperature. In addition, greater control and precision of the oxidation step may be achieved at a lower temperature because the vibrations of the lattice atoms interfere less with the penetration of the ions into the lattice. Therefore, step C may be carried out at a temperature of less than 50° C., for example between 10 and 50° C., such as around 30° C. However, in some circumstances, in order to increase the rate of oxidation, heat may be applied to the surface. The upper limit of the temperature of the surface may be determined by the tolerance limit of layers already deposited on the surface, or by the properties of any mask layer deposited on the surface. Typically, the temperature will be below 300° C.

Before the second plasma is formed in step D, the chamber in which the plasma is generated should usually be purged of oxygen. This means that the composition of the second plasma in step D may be more precisely controlled.

In step D, a second plasma is generated from a second gas. The second gas comprises a fluorine-containing species. This may comprise a fluorocarbon. A fluorocarbon is defined as used herein as a molecule that contains both fluorine and carbon. It may contain simply these two elements or it may contain additional elements. For example, it may additionally contain hydrogen.

The second gas may be, for example, either a fluorocarbon by itself or a fluorocarbon combined with a carrier gas, such as neon, helium and/or argon. The carrier gas is effectively inert in its neutral form and only when it has been ionized can the carrier gas ions contribute to reaction at the surface of the substrate. The carrier gas may be incorporated to dilute the fluorocarbon, so that reaction may be carried out in a controlled manner.

The second gas may comprise CF₄, also known as Freon 14. Other examples of fluorocarbon gas which may be used include CHF₃, also known as Freon 23, c-C₄F₈ (octafluorocyclobutane), CH₂F₂, O₂F₈, C₄F₆ (hexafluorobuta-1,3-diene) and C₅F₈.

The second gas may be provided oxygen-free, either substantially (e.g. less than 0.05%) or completely. The present inventors have found that a thin layer of fluorocarbon film builds up on the substrate surface during step E. The presence of this film is advantageous as described below, and oxygen, if present, tends to oxidize this film.

The thin film is formed from the plasma comprising the fluorocarbon. The thickness of this film depends on the substrate at the surface. The build-up of the polymer is greater on the non-oxidized substrate (e.g. silicon or silicon nitride) than on the oxidized substrate (e.g. silicon dioxide). This film inhibits etching of the surface by the fluorocarbon plasma. Accordingly, the etching process is made even more selective by the presence of this film because the film causes reaction at the oxidized surface to be favoured over reaction at the non-oxidized surface. This is supported by other work, for example M. Schaepkens et al.; J. Vac. Sci. Tech. 17, 26 (1999), in particular FIGS. 4 and 6, and T. Standaert et al.; J. Vac. Sci. Tech. 22, 53 (2004).

The first gas may be provided in step A at a pressure of 0.1 Pa to 10 Pa, for example 0.5 to 10 Pa. The plasma may be generated at a power of 50 watts to 10 kilowatts in a plasma chamber, for example 50 watts to 3 kilowatts. This power may be provided by radio frequency waves with an oscillation frequency of between 1 MHz and 20 GHz, for example below 3.0 GHz, such as at 13.56 MHz. The plasma density may be 1.0×10⁸ cm³ to 1.0×10¹³ cm³, for example 1.0×10¹⁰ cm³ to 1.0×10¹² cm³.

In step E, at least a portion of the second plasma is contacted with the surface of the substrate. This may be supplied at a flow rate of, for example, between 5 and 10,000 sccm, for example between 5 and 100 sccm.

The etching process in step E is advantageous because it causes etching of one material in preference to another material. For example, this process etches oxidized materials such as silicon dioxide and silicon oxynitride in preference to non-oxidized materials such as silicon and silicon nitride. The present inventors suggest that this may be for two reasons. Firstly, as described above, a film of fluorocarbon polymer is deposited on the surface during the etching process. The thickness of this film is dependent on the substrate on which the film is deposited. For example, the thickness of the film deposited on oxidized materials such as silicon dioxide is much less thick than that deposited on either non-oxidized materials such as silicon or silicon nitride. This film reduces the rate of etching, and therefore the rate of etching of the oxidized substrate such as silicon dioxide is greater than that of the non-oxidized substrate.

Secondly, the present inventors suggest that the reaction of a fluorocarbon plasma with an oxidized surface is favoured over reaction with a non-oxidized surface. This may be because reaction with an oxidized surface may lead to the formation of oxides of carbon (CO or CO₂) which are thermodynamically favourable, whereas reaction with a non-oxidized surface does not lead to the formation of such thermodynamically-favoured products. In addition, the present inventors have understood that when a fluorocarbon reacts with a non-oxidized surface, carbon residues may build up on the surface. These residues inhibit the surface etching, which therefore cause a slower overall rate of a non-oxidized surface.

Selectivity of this type is particularly important when etching very thin layers. The present inventors have recognised that in etching a layer of, for example, up to 5 nm thickness, selectivity is particularly important so that only the thin layer is etched and not the underlying layer on which the thin layer is deposited. The present inventors have also recognised that this is not sufficiently achieved in the prior art.

In step E, the portion of the plasma contacting the surface may contain only ions. These ions may be extracted from a plasma chamber in an analogous process to that described for step B. As will be appreciated, ideally only ions will be extracted from the plasma; however, due to experimental considerations, the ions may contain a small portion of neutral species (for example, less than 10%, such as less than 2%).

Furthermore, the ions contacting the surface may have a predetermined energy. For example, the ions may have an energy of less than the physical sputtering threshold energy of the surface of the substrate. For example, the ions may have an energy of less than 30 eV, or even less than 20 eV, for example in the range of 10 to 20 eV. As described for step C, the ions may be given a particular energy by accelerating with a potential.

It will be understood that, because of experimental considerations, substantially or essentially all of the ions may have an energy within the thresholds described above. For example, the portion of the plasma contacted with the surface may contain a total of 5% by number of its species with an energy greater than the above upper limits and less than any lower threshold limit (i.e. 95% of the ions are within the given range). For example, a total of 1% by number of the species may beyond the given thresholds.

A means of collimating the ions may also be provided. As a result, the direction of the ions is even more precisely controlled, leading to the more controlled etching of the substrate.

The ions contacting the surface will usually be positive ions because these are easier to extract from the plasma sheath. For example, in the case of a fluorocarbon plasma, these ions may have the general formula CFₓ⁺.

One advantage of selecting ions for contacting the surface in step E may be that this leads to a more controlled, and therefore more selective etching reaction. For example, neutral species may react in a different manner to charged species, and therefore any unwanted side-reactions caused by the presence of neutral species may be minimized by having only ions contacting the surface in step E.

When ions of a particular energy range are selected, the thickness of the inhibiting fluorocarbon film deposited on the surface during etching may also be controlled. Generally, the higher the energy of the ions contacting the surface, the thicker the film on the surface will be. This may lead to an increase in selectivity of etching of one material over another, because the increase in the thickness of the film may be dependent on the substrate beneath the film. However, in order for the etching process to be practical, the energy of the ions should not be too high otherwise sputtering may occur, dependent on the substrate in question as described above. Accordingly, the etch rate is generally increased by an increase in ion energy, but the ion energy should not be too high to prevent sputtering and cause surface damage.

The substrate temperature in step E may also be used to control the selectivity and etch rate. By increasing the temperature, the etch rate generally increases but the selectivity generally decreases. These are therefore counterbalancing factors. The temperature for the second step may therefore be less than 100° C., for example in the range of 10 to 50° C. The maximum temperature at which etching may be carried out is determined by the tolerance limit of films already deposited on the surface, or by the properties of any mask layer deposited on the surface. Typically, the temperature will be below 300° C.

The steps of the present invention (in all its embodiments, in particular this first embodiment) can be easily repeated using the same apparatus. Steps A to E described above can therefore optionally be repeated to etch to the desired depth. Accordingly, a layer can be controllably and precisely etched at typically a nanometer at a time (i.e. per etch cycle). This may present an advantage over prior art ALE methods that have a very slow etch rate.

Before the cycle is repeated, the chamber in which the plasma is generated should usually be purged of any fluorocarbon gas remaining in it. This means that the composition of the first plasma in step A may be precisely controlled.

A typical process sequence will include many cycles of oxidation of substrate surface using oxygen ions extracted from an oxygen plasmas, purge of oxygen from plasma chamber, etching using fluorocarbon plasma, and purging of fluorocarbon gases from the plasma chamber. When the steps are repeated, oxygen ions will also clean any carbon residues on the surface left from the etch step.

The substrate used in the present invention may be generally described as an oxidizable material. This material will be oxidized under the reaction conditions of steps A to C of the present invention, for example by low energy oxygen ions. Examples of materials suitable for use in the present invention include materials comprising one or more of Si, Ge, Ru, Mo, W, and SiGe. The substrate may also be, for example, a single crystal or polycrystalline.

The method of the present invention in its first embodiment may be used to etch a very thin layer deposited on an underlying substrate. Examples include the etching of sub-10 nm metal gates on high-k dielectrics and very thin Si on insulator. For example, the thin layer may be up to 5 nm thickness. As explained above, the method of the present invention in its first embodiment may be particularly suited to etching such a substrate because of its potential selectivity. In particular, the method may be suitable for use in the nanoscale manufacturing of materials (for example of 22 nm or 35 nm technology node).

The method of the present invention in its first embodiment may be used with or without the presence of a masking layer. Features already present on the surface may also act as a mask. Methods of forming and removing mask layers on a substrate are well-known in the prior art. The mask may, for example, be formed by lithography of a polymer absorbed onto the surface of the substrate and etching the masking layer underneath it. The composition of the mask layer is selected so that it is stable to the etching conditions, so that it is not reactive under the conditions of either step C or step E, in particular that the mask does not react with oxygen ions (whether it be positive or negative ions, dependent on the processing conditions in question).

In a second embodiment, the present invention provides a method for etching a substrate in the manufacture of a semiconductor device, the method comprising:
(A) forming a first plasma from a first gas comprising a fluorocarbon;
(B) contacting the surface of the substrate with at least a portion of the first plasma;
(C) forming a second plasma from a second gas comprising one or more of an oxygen-containing species, a nitrogen-containing species and an inert gas;
(D) extracting ions from the second plasma; and
(E) contacting the surface of the substrate with the ions extracted from the second plasma.

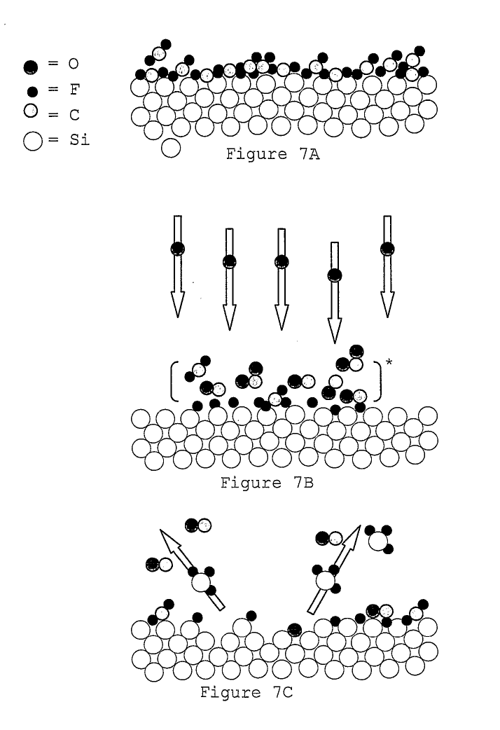

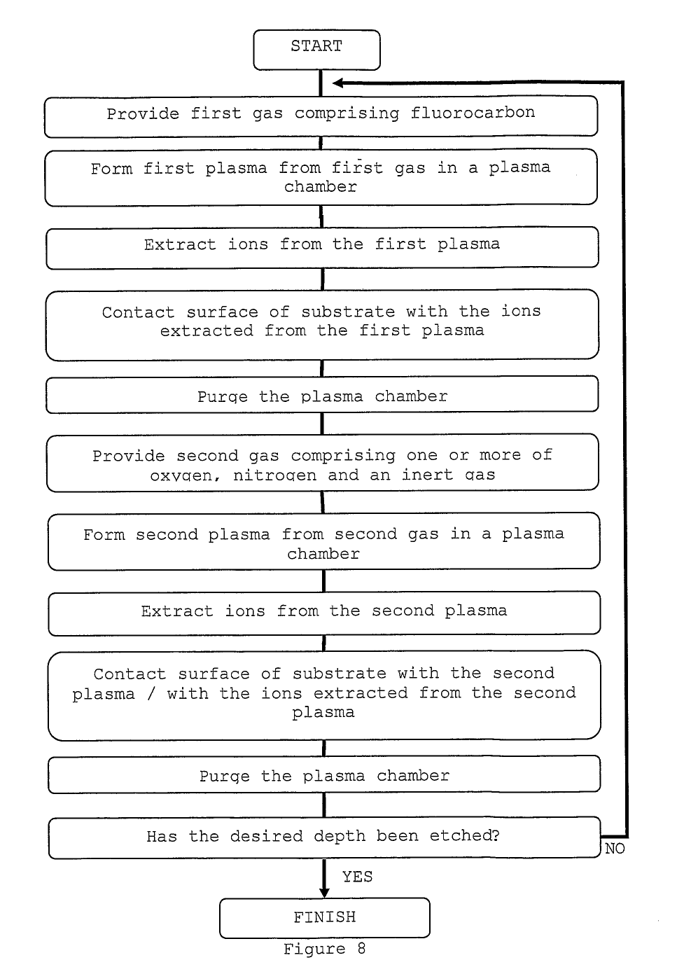

The method of the present invention according to the second embodiment is illustrated in FIGS. 7 and 8. FIG. 7A shows a layer of fluorocarbon deposited on the substrate (in this case silicon) surface, which has been deposited from a fluorocarbon based plasma. The substrate is then exposed to ions extracted from a plasma comprising one or more of oxygen, nitrogen and an inert gas. The ions extracted from the plasma cause the fluorocarbon layer to decompose to produce F- and C-containing reactive species on the surface. These reactive species then react with the substrate material, as illustrated in FIG. 7B. The reaction results in gaseous products and these products are then removed, as shown in FIG. 7C. The depth of one cycle of etching is illustrated by ‘d’ in FIG. 3B or 3C.

In this embodiment, the present inventors have recognised that the prior art method of ALE may be both precise and selective, but is impractically slow when applied to etching more than a few atomic layers. The amount of material removed in a cycle of ALE is limited by the chemisorption of only one monolayer of halogen onto the surface in the first step of the cycle. Because only a certain amount of halogen can be absorbed onto the surface, only a certain amount of material at the surface can be removed.

The present inventors have therefore devised an alternative method of absorbing an etching agent onto the surface of the substrate. In steps A and B of this embodiment, the surface is exposed to a fluorocarbon gas-containing plasma. This causes a fluorocarbon film to be deposited on the surface of the substrate. This film is thought to comprise multilayers of a fluorocarbon polymer. The present inventors have therefore found a way so that the amount of etching agent at the surface is no longer limited by the formation of a monolayer at the surface.

The present inventors have recognised that in etching a layer of, for example, 5 nm or less thickness, selectivity is particularly important so that only the thin layer is etched and not the underlying layer on which the thin layer is deposited. The present inventors have also recognised that this is not sufficiently achieved in some of the prior art etching methods. However, this may be achieved by this second embodiment.

Once the surface has been exposed to the fluorocarbon plasma, it is then exposed to a second plasma which has been formed from a second gas comprising one or more of an oxygen-containing species, a nitrogen-containing species and an inert gas. The second gas may comprise, for example, oxygen and/or nitrogen and/or an inert species. Energy is then transferred from the ions in the second plasma to the fluorocarbon physically absorbed on the surface, causing the fluorocarbon to decompose into F- and C-containing reactive species. The fluorine-containing reactive species are thought to then quickly react with the surface, forming SiFₓ-type (gaseous) species. The whole system is still in an excited state (as indicated by the * in FIG. 7B), and the silicon fluorides, once formed, have the energy to desorb from the surface. This continues until there is no fluorocarbon left at the surface. Accordingly, the extent of etching is dependent on the amount of fluorocarbon absorbed on the surface.

If the second plasma comprises either nitrogen-containing species and/or oxygen-containing species, this may have the advantage that oxygen and/or nitrogen react with the carbon-containing species formed on the surface. Oxides or nitrides of carbon may then desorb from the surface at the same time as the silicon fluorides. The oxygen and/or nitrogen thereby help to ‘clean’ the surface in situ, enhancing the rate and efficiency of the etching process.

In this second embodiment ions may be extracted from the plasma formed from the second gas comprising one or more of oxygen-containing species, nitrogen-containing species and an inert gas, and then these ions are brought into contact with the substrate. The present inventors have found that this may be advantageous because the ion energy can be more precisely controlled. It should be noted that neutral species can also be utilized for the deposition or etch process.

Turning to the individual steps of the second embodiment of the present invention, in step A the first gas from which the plasma is formed may be one or more fluorocarbons by themselves. Alternatively, the first gas may be or may comprise fluorocarbon and a carrier gas, such as an inert gas, for example one or more of argon, helium and neon. The carrier gas is effectively inert in its neutral form and it does not detriment the reaction of the fluorocarbon plasma with the surface. It should be noted that the carrier gas, when in its ionized form, can play a role in fluorocarbon film deposition. The carrier gas may be incorporated to dilute the fluorocarbon, so that reaction may be carried out in a controlled and uniform manner.

The first gas may comprise CF₄, also known as Freon 14. Other examples of fluorocarbon gas which may be used include CHF₃, also known as Freon 23, c-C₄F₈ (octafluorocyclobutane), CH₂F₂, C₂F₆, C₄F₆ (hexafluorobuta-1,3-diene) and C₅F₈.

The first gas may be provided without oxygen, either substantially (e.g. less than 0.05%) or completely. Oxygen may react with the fluorocarbon deposited on the surface, thereby reducing the thickness of the film deposited on the surface and the overall rate of etching.

The first gas may be provided in step A at a pressure of 0.1 Pa to 10 Pa, for example 0.5 to 10 Pa. The plasma may be generated at a power of 50 watts to 10 kilowatts in a plasma chamber, for example 50 watts to 3 kilowatts. This power may be provided by radio frequency waves with an oscillation frequency of between 1 MHz and 20 GHz, for example below 3.0 GHz, such as at 13.56 MHz. The plasma density may be 1.0×10⁸ cm³ to 1.0×10¹⁸ cm³, for example 1.0×10¹⁰ cm³ to 1.0×10¹² cm³.

In step B, at least a portion of the plasma generated in step A is contacted with the surface of the substrate. The fluorocarbon film is thereby deposited on the substrate.

In this step, the portion of the plasma contacting the surface may contain only ions. Ions may be extracted from the first plasma by providing an outlet to a plasma chamber. The ion energy may be precisely controlled using electrostatic and/or electromagnetostatic lenses in which electric and magnetic fields are used to appropriately increase or decrease ion energy. Ions are extracted from the plasma sheath at the outside of the plasma chamber, and may be accelerated to have a predetermined energy by the potential.

It will be understood that, while it is beneficial in certain cases to extract only ions from the plasma without any neutral species, due to practical considerations a small number of neutral species may also be extracted from the plasma (for example less than 10% by number, such as less than 2%). In other circumstances, neutral species may play a beneficial role in the etch or deposition process and they can also be utilized accordingly.

Furthermore, the ions contacting the surface may have a predetermined energy. The upper limit of ion energy may be selected to be the point at which the plasma starts to significantly induce etching of the surface on its own. Therefore the ion energy may be selected so that only deposition of the fluorocarbon onto the surface takes place. This energy is dependent on the substrate. As an example, the ions may have an energy of less than the physical sputtering threshold energy of the surface. The ions may have an energy less than 30 eV, or even less than 20 eV, for example in the range of 5 to 15 eV. In particular, the ions may be given a particular energy by accelerating with a given potential.

It will be understood that, because of experimental considerations, substantially or essentially all of the ions may have an energy within the thresholds described above. For example, the portion of the plasma contacted with the surface may contain a total of 5% by number of its species with an energy greater than the above upper limits and less than any lower threshold limit (i.e. 95% of the ions are within the given range). For example, a total of 1% by number of the species may beyond the given thresholds.

The present inventors have recognised that the thickness of the fluorocarbon film deposited on the surface is dependant on the energy of the ions contacting the surface in step B. Accordingly, because the thickness of the film can be controlled, so can the overall extent of etching. This therefore has the potential to be a precisely controlled process.

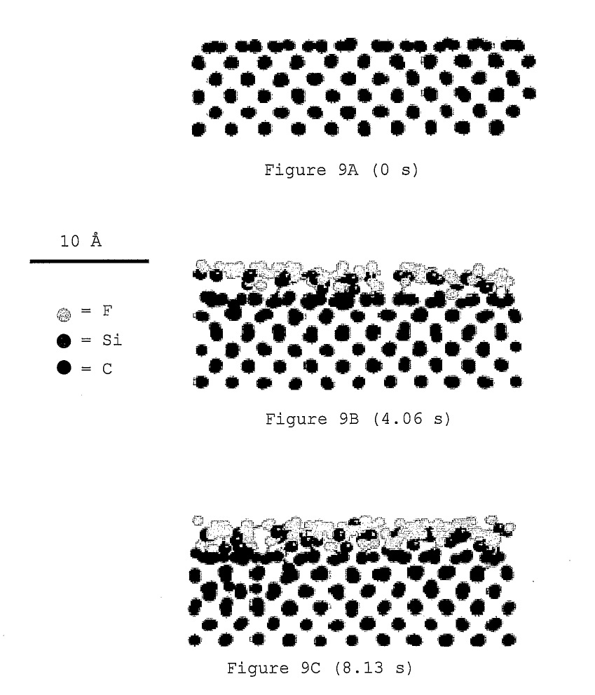

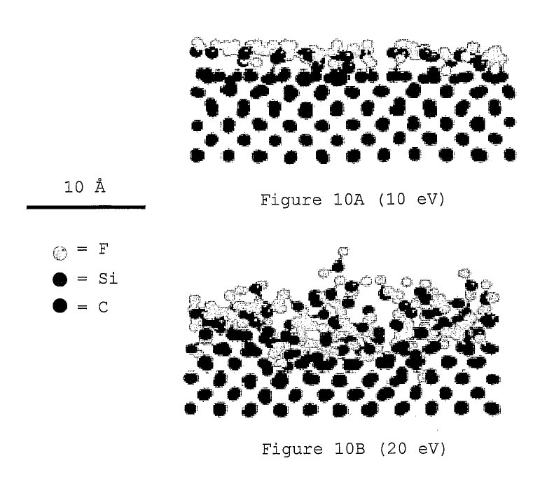

In order to illustrate this control, a series of computer simulations has been carried out by the present inventors to model the deposition of the fluorocarbon from the plasma onto the surface. These simulations were carried out using the molecular dynamics method. Details of the computational model that is used for these simulations is described in the following paper: V. V. Smirnov, A. V. Stengach, K. G. Gaynullin, V. A. Pavlovsky, S. Rauf, P. J. Stout, and P. L. G. Ventzek, J. Appl. Phys. 97, 093302 (2005). Representative results of these simulations are illustrated in FIGS. 9 and 10.

FIG. 9 shows the rate of deposition of the fluorocarbon onto a silicon surface over time. The silicon atoms are shown in dark grey; carbon atoms are shown in black, and fluorine atoms are shown in light grey. The simulation was carried out with CF₂⁺ ions with an energy on 10 eV with a collision rate with the surface of 1.0×10¹⁵ cm⁻² s⁻¹. The lattice is shown in FIG. 9A prior to deposition; in FIG. 9B the lattice is shown having been exposed for 4.06 seconds to the ions; finally, the lattice is shown in FIG. 9C having been exposed to the ions for 8.13 seconds. It can be seen that the fluorocarbon film is formed to a certain thickness, and does not significantly grow in thickness beyond this. In other words, the thickness of the fluorocarbon film is self-limiting, and once sufficient fluorocarbon has been deposited, the fluorocarbon film doesn't grow any further. This step is typically quite fast, taking between 4 to 6 seconds even at low energies.

FIG. 10 shows the deposition of the fluorocarbon film dependent on the energy of ions used to deposit the film Both lattices have been exposed to CF₂⁺ ions for 4.06 seconds with a collision rate of 1.0×10¹⁵ cm⁻² s⁻¹. The difference between the two simulations is that the result in FIG. 10A was obtained with ions having 10 eV of energy, whereas the result in FIG. 10B was obtained with ions having 20 eV of energy. It is observed that more reaction occurs at higher energy and the fluorocarbon film is correspondingly thicker.

In addition, these simulations also demonstrate that the amount of fluorine and carbon actually in the film is increased at higher ion energy. Accordingly, not only is the thickness of the film increased at higher ion energy, so is the amount of fluorocarbon in the film. Therefore the overall rate of etching is also increased.

Accordingly, these simulations demonstrate that the thickness of the fluorocarbon film is predictable given predetermined reaction conditions. Therefore, by selecting a predetermined range of energies for the ions, the deposition of the fluorocarbon film may be precisely controlled.

However, the present inventors have found that the film may not be deposited at too high an energy. This is because high energy ions may cause chemical reaction of the top layers of the substrate. For example, if the substrate is a single crystal of silicon, using high energy ions may cause the amorphization of the top layers of the silicon.

Furthermore, an increase in ion energy will also increase the F/C ratio of the film as C and F are sputtered at different rates. Therefore, in order to be able to reliably predict the rate and extent of etching, the energy of the ions may be selected to be in a predetermined range.

In step B, there is no need to apply any heat to the substrate. Therefore the substrate may be up to 50° C., for example in the temperature range of 10 to 50° C. However, in some circumstances it may be considered beneficial to apply heat. An increase in temperature generally leads to an increase the rate of deposition of the fluorocarbon, and therefore temperature may also be used to control the thickness of the fluorocarbon film. The maximum temperature at which etching may be carried out is determined by the tolerance limit of layers already deposited on the substrate, or by the properties of any mask layer deposited on the surface. Typically, the temperature will be below 300° C.

Before the second plasma is formed in step C, the chamber in which the plasma is generated should usually be purged of fluorocarbon. This means that the composition of the second plasma in step C may be precisely controlled.

In step C, the second gas from which the second plasma is formed may be pure oxygen. Alternatively, it may be pure nitrogen. Alternatively, it may be pure inert gas, such as argon or neon. The inert gas may also function as a carrier gas when used in combination with an oxygen- or nitrogen-containing species. The advantages of using a carrier gas were described in relation to the formation of the first plasma.

The first gas may be provided in step A at a pressure of 0.1 Pa to 10 Pa, for example 0.5 to 10 Pa. The plasma may be generated at a power of 50 watts to 10 kilowatts in a plasma chamber, for example 50 watts to 3 kilowatts. This power may be provided by radio frequency waves with an oscillation frequency of between 1 MHz and 20 GHz, for example below 3.0 GHz, such as at 13.56 MHz. The plasma density may be 1.0×10⁸ cm³ to 1.0×10¹³ cm³, for example 1.0×10¹⁰ cm³ to 1.0×10¹² cm³.

Either the plasma may be contacted directly with the plasma generated in step C, or else ions may be extracted from the plasma (in the optional step D). The extraction of the ions may be carried out in a similar manner as described above for the first plasma. It is beneficial to contact the surface with only ions because neutral species may cause unwanted side reactions on the surface, leading to reduced selectivity and precision. It will be understood that, while it is beneficial to extract only ions from the plasma without any neutral species, due to practical considerations a small number of neutral species may also be extracted from the plasma (for example less than 10% by number, such as less than 2%).

In step E, the ions extracted from the plasma in step D are contacted with the surface of the substrate.

Etching occurs by chemical reaction of the substrate and the reactive C and F containing species produced in the fluorocarbon film due to oxygen or nitrogen or inert gas ions. The etching method may therefore be considered precise because the direction of etching will generally be in the direction of the flow of the ions. Accordingly, by directing the ions perpendicular to the surface, the surface may be etched in a perpendicular direction. This is particularly important when etching features onto a surface because, for example, high aspect ratios may be achieved at small (e.g. nanoscale) length scales.

The ions in step E may have a pre-determined range of energies. This allows for the more predictable and controlled etching of the surface. The range of energies of ions may be below 30 eV, or even below 20 eV, such as in the range of 5 to 15 eV. The ions must have a minimum energy, dependent on the surface, in order for the silicon fluoride species, when formed, to desorb from the surface. However, if the ions have too much energy, again dependant on the surface, unwanted sputtering may occur. Therefore the ions may have any energy less than the physical sputtering threshold energy of the surface.

It will be understood that, because of experimental considerations, substantially or essentially all of the ions may have an energy within the thresholds described above. For example, the portion of the plasma contacted with the surface may contain a total of 5% by number of its species with an energy greater than the above upper limits and less than any lower threshold limit (i.e. 95% of the ions are within the given range). For example, a total of 1% by number of the species may beyond the given thresholds.

The ions in step E may, for example, be provided at a flow rate of between 5 and 10,000 sccm (standard cubic centimetres per minute), for example between 5 and 100 sccm.

It is not necessary to apply heat to the substrate in step E. This is because reaction is driven by the energy of the plasma/ions. Therefore a typical temperature of reaction is up to 50° C., for example in the range between 10 and 50° C. However, in some circumstances, for example in order to increase the rate of reaction, a higher temperature may be sometimes used. The upper limit of the temperature of the surface may be determined by the tolerance limit of the substrate, or by the properties of any photoresist layer deposited on the surface. Typically, the temperature will be below 300° C.

The steps of the present invention (in all its embodiments, in particular this second embodiment) can be easily repeated using the same apparatus. Steps A to E described above can therefore optionally be repeated to etch to the desired depth. Accordingly, a layer can be controllably and precisely etched at typically a nanometer at a time (i.e. per etch cycle). This may present an advantage over prior art ALE methods that have a very slow etch rate.

Before repeating each cycle, the chamber in which the plasma is generated should usually be purged of the second gas mixture. This means that the composition of the first plasma in step A may be precisely controlled.

A typical process sequence will include many cycles of deposition of fluorocarbon onto the surface using fluorocarbon ions extracted from a fluorocarbon plasmas, purge of fluorocarbon from plasma chamber, etching using ions extracted from a plasma comprising on or more of an oxygen-containing species, a nitrogen-containing species and/or inert gases, and purging of oxygen-containing species and/or nitrogen-containing species and/or inert gases from the plasma chamber.

The substrate used in the present invention is suitable for use in a semiconductor device. Examples of materials suitable for use in the present invention were described in relation to the first embodiment. The substrate may be susceptible to etching by reactive fluorine species. Examples of substrates include materials comprising one or more of Si, Ge, Ru, Mo and W, such as SiO₂, Si₃N₄, SiGe, and SiON. For example the substrate may be a single crystal silicon or polycrystalline silicon substrate.

The method of the present invention in this second embodiment may be used to etch a very thin layer deposited on an underlying substrate. For example, the thin layer may be up to 5 nm thickness. As explained above, the method of the present invention may be particularly suited to etching such a substrate because of its potential selectivity. In particular, the method may be suitable for use in the manufacture of nanoscale devices (for example for the 22 nm or 35 nm technology nodes).

The method of the present invention in its second embodiment may be used with or without the presence of a masking layer. Features already present on the surface may also act as a mask. Methods of forming and removing mask layers on a substrate are well-known in the prior art. The mask may, for example, be formed by lithography of a polymer absorbed onto the surface of the substrate. The composition of the mask layer is selected so that it is stable to the etching conditions, so that it is not reactive under the conditions of either step C or step E, in particular that the mask does not react with oxygen ions (whether it be positive or negative ions, dependent on the processing conditions in question).

1. A method for etching a substrate in the manufacture of a semiconductor device, the method comprising:
contacting a surface of the substrate with ions extracted from a plasma formed from a gas comprising one or more of an oxygen-containing species, a nitrogen-containing species and an inert gas, and separately contacting the surface of the substrate with a plasma formed from a gas comprising a fluorine-containing species.

2. The method as claimed in claim 1, wherein the fluorine-containing species is a fluorocarbon.

3. The method according to claim 2, wherein the fluorine-containing species comprises one or more of CF₄, CHF₃, CH₂F₂, C₂F₆, C₄F₆, octafluorocyclobutane and C₅F₈.

4. The method according to claim 1, wherein the gas comprising the fluorine-containing species is essentially oxygen-free.

5. The method as claimed in claim 1, wherein the inert gas is a noble gas.

6. The method as claimed in claim 4, wherein the inert gas comprises one or more of helium, neon and argon.

7. The method as claimed in claim 1, wherein the oxygen-containing species comprises one or more of O₂, CO, CO₂, N₂O and H₂O.

8. The method as claimed in claim 1, wherein the nitrogen-containing species comprises N₂.

9. The method as claimed in claim 1, the method comprising:
(A) forming a first plasma from a first gas comprising an oxygen-containing species;
(B) extracting ions from the first plasma;
(C) contacting a surface of the substrate with the ions extracted from the first plasma;
(D) forming a second plasma from a second gas comprising a fluorine-containing species; and
(E) contacting the surface of the substrate with at least a portion of the second plasma.

10. The method according to claim 9, wherein the portion of the plasma contacting the surface of the substrate in step (C) and/or step (E) contains essentially only ions.

11. The method according to claim 10, wherein the ions contacting the surface of the substrate in step (C) and/or step (E) are positive ions.

12. The method according to claim 10, wherein the ions contacting the surface in step (C) and/or step (E) have an energy less than the physical sputtering threshold energy of the surface.

13. The method according to claim 9, wherein steps A to E are repeated until a pre-determined semiconductor depth has been etched.

14. The method according to claim 9, wherein the surface of the substrate comprises an oxidizable material.

15. The method according to claim 9, wherein the surface of the substrate comprises one or more of Si, Ge, Ru, Mo and W.

16. The method according to claim 9, wherein the temperature of the substrate in step (C) and/or step (E) is less than 300° C.

17. A method according to claim 1, the method comprising:
(A) forming a first plasma from a first gas comprising a fluorocarbon;
(B) contacting the surface of the substrate with at least a portion of the first plasma;
(C) forming a second plasma from a second gas comprising one or more of an oxygen-containing species, a nitrogen-containing species and an inert gas;
(D) extracting ions from the second plasma; and
(E) contacting the surface of the substrate with the ions extracted from the second plasma.

18. The method according to claim 17, wherein the portion of the plasma contacting the surface of the substrate in step (B) and/or step (E) contains essentially only ions.

19. The method according to claim 18, wherein the ions contacting the surface in step (B) and/or step (E) of the substrate are positive ions.

20. The method according to either claim 18, wherein essentially all of the ions contacting the surface in step (B) and/or step (E) have an energy less than the physical sputtering threshold energy of the surface.

21. The method according to claim 17, wherein steps A to E are repeated until a pre-determined semiconductor depth has been etched.

22. The method according to claim 17, wherein the surface of the substrate comprises one or more of Si, Ge, Ru, Mo and W.

23. The method according to claim 17, wherein the temperature of the substrate in step (B) and/or step (E) is less than 300° C.
